(19) United States
(12) Patent Application Publication
(10) Pub. No.: US 2019/0377232 A1
(43) Pub. Date: Dec. 12, 2019

(54) ACTIVE MATRIX SUBSTRATE AND METHOD FOR MANUFACTURING THE SAME

(71) Applicant: Sharp Kabushiki Kaisha, Sakai City (JP)

(72) Inventor: Hidenobu KIMOTO, Sakai City (JP)

(21) Appl. No.: 16/432,221

(22) Filed: Jun. 5, 2019

Related U.S. Application Data
(60) Provisional application No. 62/683,689, filed on Jun. 12, 2018.

(51) Int. Cl. G02F 1/1343; H01L 27/12; G02F 1/1362; G02F 1/1368; H01L 21/306; H01L 21/3213

(52) U.S. Cl. CPC G02F 1/134363; H01L 27/124; H01L 27/1248; G02F 1/13439; H01L 27/1288; H01L 21/02532; G02F 1/1368; H01L 21/30604; H01L 21/32134; G02F 2001/136295; G02F 2001/134318; G02F 1/136286

(57) ABSTRACT

An active matrix substrate of a liquid crystal panel of an FFS mode includes gate lines, data lines, pixel circuits each including a switching element and a pixel electrode, a protective insulating film formed in a layer over these elements, and a common electrode formed in a layer over the protective insulating film. The data line includes a lower layer conductor part formed using indium tin oxide together with the pixel electrode, and an upper layer conductor part formed using molybdenum niobium and an aluminum alloy. The lower layer conductor part is formed in a disconnected shape at a position of the switching element, and the upper layer conductor part is formed in a continuous shape so as to overlap with the lower layer conductor part. With this, an active matrix substrate capable of preventing a disconnection failure of the data line and an alignment failure is provided.

### CROSS-REFERENCE TO RELATED APPLICATION

This application claims the benefit of U.S. Provisional Patent Application No. 62/683,689 filed on Jun. 12, 2018, and entitled. “Active Matrix Substrate And Method For Manufacturing The Same”, which is incorporated herein by reference in its entirety.

### BACKGROUND OF THE INVENTION

### Field of the Invention

The present invention relates to a display device, and particularly relates to an active matrix substrate having a common electrode, and a method for manufacturing the same.

### Description of Related Art

A liquid crystal display device has been widely used as a thin, light-weight, and low power consumption display device. A liquid crystal panel included in the liquid crystal display device has a structure formed by attaching an active matrix substrate and a counter substrate together, and providing a liquid crystal layer between the two substrates. Gate lines, data lines, and pixel circuits each including a thin film transistor (hereinafter referred to as TFT) and a pixel electrode are formed on the active matrix substrate.

As a system for applying an electric field to the liquid crystal layer of the liquid crystal panel, a vertical electric field system and a lateral electric field system are known. In a liquid crystal panel of the vertical electric field system, an almost vertical electric field is applied to the liquid crystal layer by using the pixel electrode and a common electrode formed on the counter substrate. In a liquid crystal panel of the lateral electric field system, the common electrode is formed on the active matrix substrate together with the pixel electrode, and an almost lateral electric field is applied to the liquid crystal layer by using the pixel electrode and the common electrode. The liquid crystal panel of the lateral electric field system. is advantageous in having a wider view angle than the liquid crystal panel of the vertical electric field system.

As the lateral electric field system, an IPS (In-Plane Switching) mode and an FFS (Fringe Field Switching) mode are known. In a liquid crystal panel of the IPS mode, the pixel electrode and the common electrode are each formed in a comb teeth shape, and are arranged so as not to overlap with each other in a planar view. In a liquid crystal panel of the FFS mode, a slit is formed either in the common electrode or the pixel electrode, and the pixel electrode and the common electrode are arranged so as to overlap with each other via a protective insulating film in the planar view. The liquid crystal panel of the FFS mode is advantageous in having a higher aperture ratio than the liquid crystal panel of the IPS mode.

An active matrix substrate of the liquid crystal panel of the FFS mode is manufactured using five or six photomasks. International Publication No. WO2016/21319 discloses a method for manufacturing the active matrix substrate using six photomasks. This document discloses forming the pixel electrode using IZO (Indium Zinc Oxide) in a fourth process after forming a source layer pattern using MoNb (molybdenum niobium) in a third process The data line of the active matrix substrate manufactured by this method has a two-layer structure including a lower layer formed of MoNb and an upper layer formed of IZO.

A data line having a two-laver structure is also disclosed in Japanese Laid-Open Patent Publication No. Hei 4276723, Japanese Laid-Open Patent Publication No. Hei 11-295760, and Japanese Laid-Open Patent Publication No. Hei 11-326950, Japanese Laid-Open Patent Publication No. Hei 4-276723 discloses a data line having a lower layer formed of ITO (Indium Tin Oxide) and an upper layer formed using Mo (molybdenum) and being wider than the lower layer, Japanese Laid-Open Patent Publication No. Hei 11-295760 discloses a data line having a lower layer formed of ITO and an upper layer formed using Al (aluminum) and being wider than the lower layer at an end of an intersecting portion with a scanning line Japanese Laid-Open Patent Publication No. Hei 11-326950 discloses a data line formed by etching a transparent conductor layer and a metal layer in a same pattern.

As described in International Publication No. WO2016/21319, a case where the source layer pattern is formed using MoNb in the third process and the pixel electrode is formed using IZO in the fourth process is considered. In this case, phosphoric-nitric-acetic acid is used as an etching solution in the third and fourth processes. However, if etching is performed using phosphoric-nitric-acetic acid in the third process and then etching is performed using the same chemical liquid in the fourth process, overetching occurs. Thus, if there is a pattern failure on the data line, the data line is likely to be disconnected.

Furthermore, in the active matrix substrate disclosed in International Publication No. WO2016/21319, a drain electrode and a source electrode of the TFT have a two-layer structure as with the data line. Thus, a film thickness becomes thick at a position where the TFT is formed, and a step difference occurs between the position where the TFT is formed and a surrounding portion. When a rubbing process is performed on the active matrix substrate having the step difference, an alignment failure may occur and a display failure called a streak may occur.

### SUMMARY OF THE INVENTION

Therefore, providing an active matrix substrate capable of preventing a disconnection failure of a data line and an alignment failure is taken as a problem.

(1) An active matrix substrate according to some embodiments of the present invention includes: gate lines; data lines; pixel circuits arranged corresponding to intersections of the gate lines and the data lines and each including a switching element and a pixel electrode; a protective insulating film formed in a layer over the gate line, the data line, the switching element, and the pixel electrode; and a common electrode formed in a layer over the protective insulating film, the data line includes a lower layer conductor part formed using indium tin oxide together with the pixel electrode, and an upper layer conductor part formed using a metal material other than indium tin oxide, the lower layer conductor part is formed in a disconnected shape at a position of the switching element, and the upper layer conductor part is formed in a continuous shape so as to overlap with the lower layer conductor part.

According to the above active matrix substrate, it is possible to prevent overetching of the lower layer conductor part of the data line by suitably selecting an etching solution used for forming the pixel electrode and the like, and an etching solution used for forming the source layer pattern. Furthermore, the data line has a redundant structure including the lower layer conductor part and the upper layer conductor part. Therefore, a disconnection failure of the data line can be prevented. Furthermore, since the lower layer conductor part is not formed at the position of the switching element, a step difference between the position where the switching element is formed and a surrounding portion can be reduced, an alignment failure when a rubbing process is performed can be prevented, and a streak can be prevented.

(2) The active matrix substrate according to some embodiments of the present invention has the configuration of above (1), and the lower layer conductor part is formed in a disconnected shape at an arrangement position of the gate line.

(3) The active matrix substrate according to some embodiments of the present invention has the configuration of above (1), and The upper layer conductor part is formed using molybdenum niobium and an aluminum alloy.

(4) The active matrix substrate according to some embodiments of the present invention has the configuration of above (3), and the upper layer conductor part has a three-layer structure including molybdenum niobium, the aluminum alloy, and molybdenum. niobium.

(5) The active matrix substrate according to some embodiments of the present invention has the configuration of above (1), and the upper layer conductor part is formed so as to have a line width narrower than that of the lower layer conductor part.

(6) The active matrix substrate according to some embodiments of the present invention has the configuration of above (1), and the common electrode has slits corresponding to the pixel electrode.

(7) A method for manufacturing an active matrix substrate according to some embodiments of the present invention includes: forming gate lines and gate electrodes of switching elements in a first wiring layer; forming a gate insulating film and a semiconductor film; forming a pixel electrode layer by forming pixel electrodes and lower layer conductor parts of data lines in the pixel electrode layer using indium tin oxide; forming a source layer by forming upper layer conductor parts of the data lines and conduction electrodes of the switching elements in a second wiring layer using a metal material other than indium tin oxide and patterning the semiconductor film; forming a protective insulating film in a layer over the pixel electrode; and forming a common electrode in a layer over the protective insulating film, in forming the pixel electrode layer, the lower layer conductor part is formed in a disconnected shape at a position of the switching element, and in forming the source layer, the upper layer conductor part is formed in a continuous shape so as to overlap with the lower layer conductor part.

According to the above method for manufacturing the active matrix substrate, the active matrix substrate which attains the above effects can be manufactured.

(8) The method for manufacturing the active matrix substrate according to some embodiments of the present invention has the configuration of above (7), and in forming the pixel electrode layer, the lower layer conductor part is formed in a disconnected shape at an arrangement position of the gate line.

(9) The method for manufacturing the active matrix substrate according to some embodiments of the present invention has the configuration of above (7), and in forming the source layer, the upper layer conductor part and the conduction electrode are formed using molybdenum niobium and an aluminum alloy.

(10) The method for manufacturing the active matrix substrate according to some embodiments of the present invention has the configuration of above (9), and in forming the source layer, the upper layer conductor part and the conduction electrode are formed so as to have a three-layer structure including molybdenum niobium, the aluminum alloy, and molybdenum niobium.

(11) The method for manufacturing the active matrix substrate according to some embodiments of the present invention has the configuration of above (7), in forming the pixel electrode layer, etching is performed using ferric chloride or oxalic acid, and in forming the source layer, etching is performed using an etching solution. which does not etch indium tin oxide.

(12) The method for manufacturing the active matrix substrate according to some embodiments of the present invention. has the configuration of above (11), and in forming the source layer, etching is performed using phosphoric-nitric-acetic acid.

(13) The method for manufacturing the active matrix substrate according to some embodiments of the present invention has the configuration of above (7), and in forming the source layer, the upper layer conductor part is formed so as to have a line width narrower than that of the lower layer conductor part.

(14) The method for manufacturing the active matrix substrate according to some embodiments of the present invention. has the configuration of above (7), and in forming the common electrode, the common electrode is formed so as to have slits corresponding to the pixel electrode.

These and other objects, features, modes and effects of the present invention will be more apparent from the following detailed description with reference to the attached drawings.

### BRIEF DESCRIPTION OF THE DRAWINGS

FIG. 1 is a block diagram showing a configuration of a liquid. crystal display device provided with an active matrix substrate according to an embodiment.

FIG. 2 is a plan view of the active matrix substrate shown in FIG. 1.

FIG. 3 is a layout diagram of the active matrix substrate shown in FIG. 1.

FIG. 4 is a diagram showing a pattern other than a common electrode of the active matrix substrate shown in FIG. 1.

FIG. 5 is a diagram showing a pattern of the common electrode of the active matrix substrate shown in FIG. 1.

FIG. 6A is a diagram. showing a method for manufacturing the active matrix substrate shown in FIG. 1.

FIG. 6B is a diagram continued from FIG. 6A.

FIG. 6C is a diagram continued from FIG. 6B.

FIG. 6D is a diagram continued from FIG. 6C.

FIG. 6E is a diagram continued from FIG. 6D.

FIG. 6F is a diagram continued from FIG. 6E.

FIG. 7 is a schematic diagram of a data line of the active matrix substrate shown in FIG. 1.

FIG. 8 is a diagram showing characteristics of etching solutions used in a manufacturing method according to the embodiment.

FIG. 9 is a diagram showing third and fourth processes of a manufacturing method according to a comparative example.

FIG. 10 is a diagram showing third and fourth processes of the manufacturing method according to the embodiment.

FIG. 11 is a sectional view of a TFT of an active matrix substrate according the comparative example.

FIG. 12 is a sectional view of a TET of the active matrix substrate shown in FIG. 1.

FIG. 13 is a diagram showing an example of failure rates of the active matrix substrates.

FIG. 14 is a diagram showing third and fourth processes of a manufacturing method according to a modification.

### DETAILED DESCRIPTION OF THE INVENTION

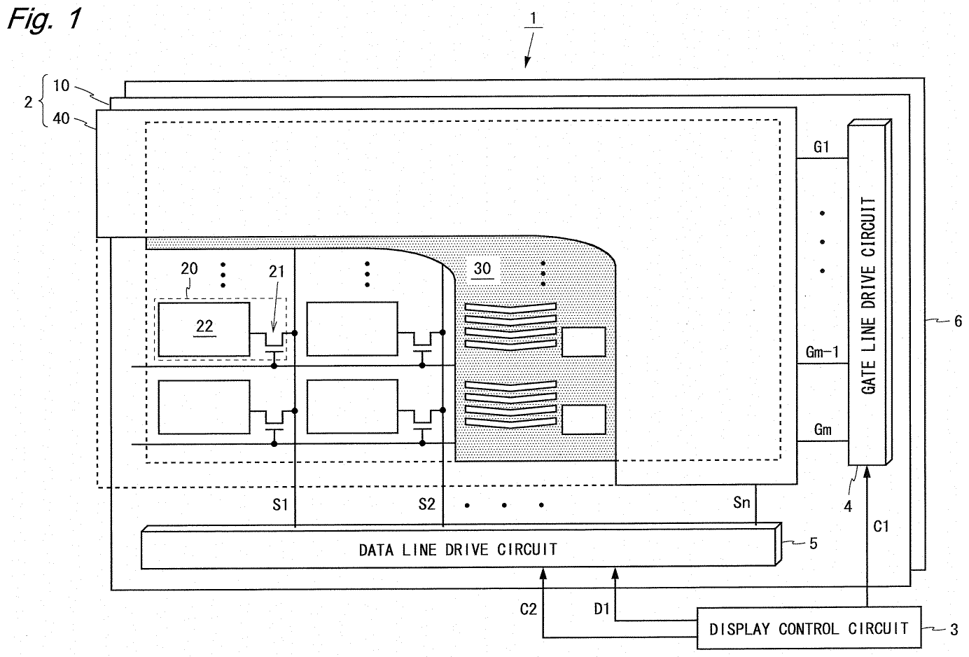

FIG. 1 is a block diagram showing a configuration of a liquid crystal display device provided with an active matrix substrate according to an embodiment. A liquid crystal display device 1 shown in FIG. 1 includes a liquid crystal panel 2, a display control circuit 3, a gate line drive circuit 4, a data line drive circuit 5, and a backlight 6. Hereinafter, m and n are integers not smaller than 2, is an integer not smaller than 1 and not larger than m, and j is an integer not smaller than 1 and not larger than n.

The liquid crystal panel 2 is a liquid crystal panel of an FFS mode. The liquid crystal panel 2 has a structure formed by attaching an active matrix substrate 10 and a counter substrate 40 together, and providing a liquid crystal layer between the two substrates. A black matrix (not shown) and the like are formed on the counter substrate 40. On the active matrix substrate 10, m gate lines G1 to Gm, n data lines S1 to Sn, (m×n) pixel circuits 20, a common electrode 30 (dot pattern portion), and the like are formed. A semiconductor chip to function as the gate line drive circuit 4 and a semiconductor chip to function as the data line drive circuit 5 are mounted on the active matrix substrate 10. Note that FIG. 1 schematically shows the configuration of the liquid crystal display device 1, and shapes of the elements described in FIG. 1 are not accurate.

Hereinafter, a direction in which the gate line extends (a horizontal direction in the drawing) is referred to as a row direction, and a direction in which the data line extends (a vertical direction in the drawing) is referred to as a column direction. The gate lines G1 to Gm extend in the row direction and are arranged in parallel with each other. The data lines S1 to Sn extend in the column direction and are arranged in parallel with each other. The gate lines G1 to Gm and the data lines S1 to Sn intersect at (m×n) points. The (m×n) pixel circuits 20 are arranged two-dimensionally corresponding to intersections of the gate lines G1 to Gm and the data lines S1 to Sn.

The pixel circuit 20 includes an N-channel TFT 21 and a pixel electrode 22. The TFT 21 included in the pixel circuit 20 in an i-th row and a j-th column has a gate electrode connected to a gate line G1, a source electrode connected to a data line Sj, and a drain electrode connected to the pixel electrode 22. A protective insulating film (not shown) is formed in a layer over the gate lines G1 to Gm, the data lines S1 to Sn, the TFT 21, and the pixel electrode 22. The common electrode 30 is formed in a layer over the protective insulating film. The pixel electrode 22 and the common electrode 30 face each other with the protective insulating film interposed therebetween. The backlight 6 is arranged on a back surface side of the liquid crystal panel 2 and irradiates a back surface of the liquid crystal panel 2 with light.

The display control circuit 3 outputs a control signal C1 to the gate line drive circuit 4, and outputs a control signal C2 and a data signal D1 to the data line drive circuit 5. The gate line drive circuit 4 drives the gate lines G1 to Gm based on the control signal C1. The data line drive circuit 5 drives the data lines S1 to Sn based on the control signal C2 and the data signal D1. More specifically, the gate line drive circuit 4 selects one gate line from among the gate lines G1 to Gm in each horizontal period (line period), and applies a high-level voltage to the selected gate line. The data line drive circuit 5 respectively applies, to the data lines S1 to Sn, n data voltages in accordance with the data signal D1 in each horizontal period. With this, n pixel circuits 20 are selected in one horizontal period, and n data voltages are respectively written to the selected n pixel circuits 20.

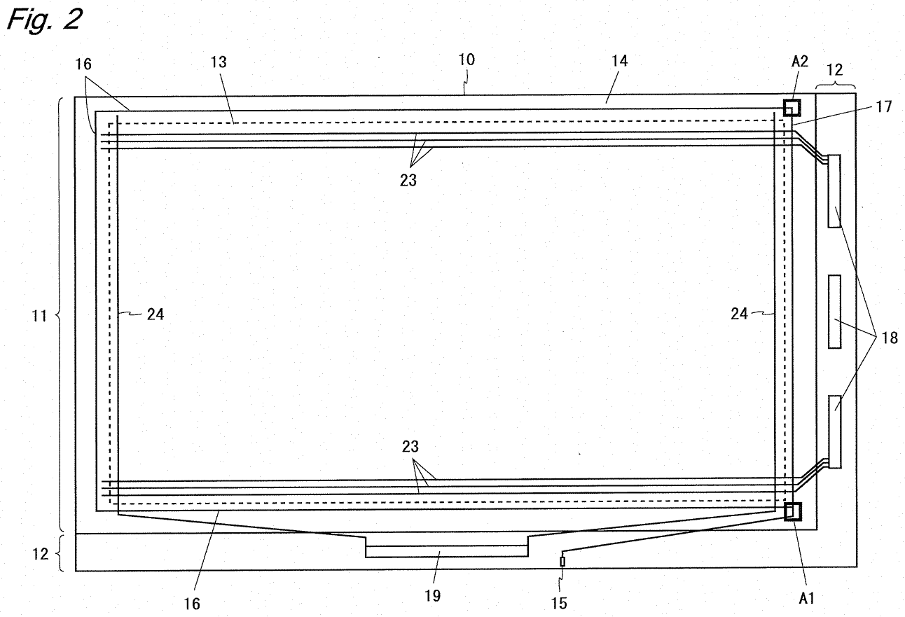

FIG. 2 is a plan view of the active matrix substrate 10. A part of elements formed on the active matrix substrate 10 is illustrated in FIG. 2. As shown in FIG. 2, the active matrix substrate 10 is divided into a counter region 11 facing the counter substrate 40, and a non-counter region 12 not facing the counter substrate 40. In FIG. 2, the non-counter region 12 is located in a right side and a lower side of the counter region 11. A display region 13 (a region shown by a broken line) for arranging the pixel circuits 20 is set in the counter region. 11. A portion remaining after removing the display region 13 from the counter region 11 is referred to as a picture-frame region 14.

The (m×n) pixel circuits 20, the m gate lines 23, and the n data lines 24 are formed in the display region 13. The (m×n) pixel circuits 20 are arranged two-dimensionally in the display region 13. An external terminal 15 for inputting a common electrode signal is provided to the non-counter region 12. For applying to the common electrode 30 the common electrode signal input through the external terminal 15, a first common main wiring 16 formed in a same wiring layer as the gate line 23 and a second common main wiring 17 formed in a same wiring layer as the data line 24 are formed in the picture-frame region 14. In FIG. 2, the first common main wiring 16 is formed in an upper side, a left side, and a lower side of the display region 13, and the second common main wiring 17 is formed in a right side of the display region 13. Furthermore, a connecting circuit (not shown) for connecting the common electrode 30, the first common main wiring 16, and the second common main wiring 17 is formed in each of an A1 part and an A2 part of FIG. 2. A mounting region 18 for mounting the gate line drive circuit 4 and a mounting region 19 for mounting the dataline drive circuit 5 are set in the non-counter region 12.

The active matrix substrate 10 is formed by forming a gate layer, a gate insulating film, a first semiconductor layer, a second semiconductor layer, a pixel electrode layer, a source layer, a protective insulating film, and a common electrode layer over a glass substrate sequentially from the lowest layer (details are described later). The gate line 23 and the first common main wiring 16 are formed in the gate layer. The data line 24 and the second common main wiring 17 are wirings having a two-layer structure formed in the pixel electrode layer and the source layer.

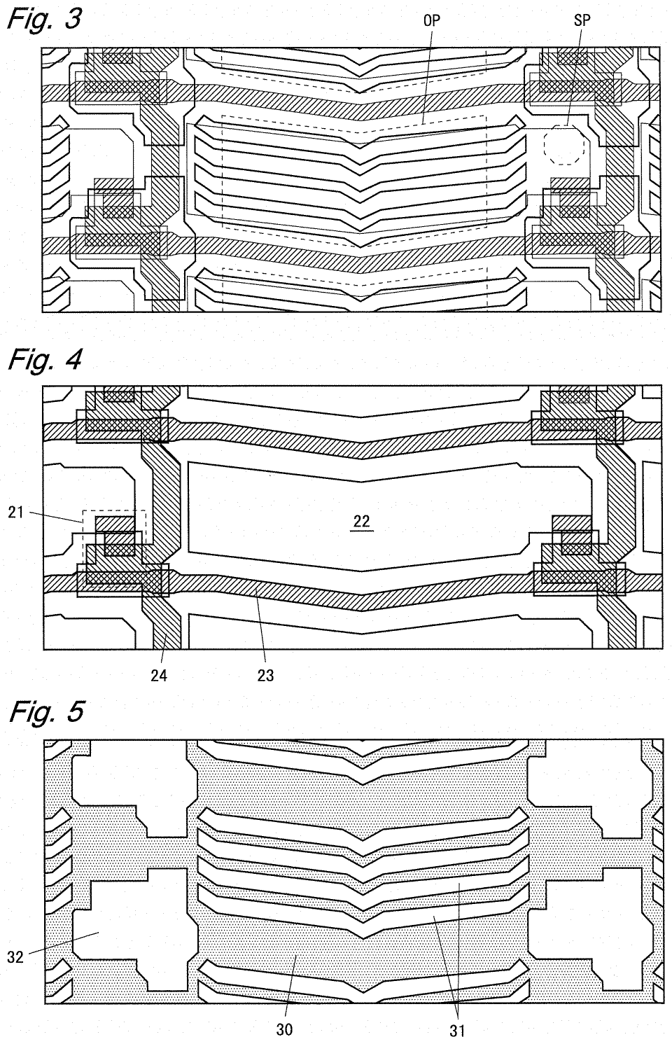

FIG. 3 is a layout diagram of the active matrix substrate 10. FIG. 3 is divided into two and is described. FIG. 4 is a diagram showing a pattern other than the common electrode 30 of the active matrix substrate 10. FIG. 5 is a diagram showing a pattern of the common electrode 30 of the active matrix substrate 10. Note that in order to make the drawings understood easily, in FIG. 3, a pattern shown in FIG. 4 is depicted with a thin line, and a pattern shown in FIG. 5 is depicted with a normal width line.

In FIG. 3, an area OP depicted with a thin broken line indicates a position of an opening formed on the counter substrate 40. An area SP depicted with a thin broken line indicates a position of a columnar spacer (not shown) provided between the active matrix substrate 10 and the counter substrate 40. The columnar spacer is provided for keeping an interval between the active matrix substrate 10 and the counter substrate 40 constant.

As shown in FIG. 4, the gate line 23 (left down oblique line portion) extends in the row direction while bending in the middle. The data line 29 (right down oblique line portion) extends in the column direction while having a protruding portion near an intersection with the gate line 23. The gate line 23 and the data line 24 are formed in different wiring layers The TFT 21 is formed near the intersection of the gate line 23 and the data line 24. The pixel electrode 22 is formed in a region separated by the gate lines 23 and the data lines 24. The TFT 21 has a gate electrode connected to the gate line 23, a source electrode connected to the data line 24, and a drain electrode connected to the pixel electrode 22. In this manner, the liquid crystal panel 2 includes the pixel circuits 20 arranged corresponding to the intersections of the gate lines 23 and the data lines 24.

The common electrode 30 is formed in a layer over the protective insulating film which is formed in a layer over the TFT 21, the pixel electrode 22, the gate line 23, and the data line 24 (that is, closer side to the liquid crystal layer). As shown in FIG. 5, the common electrode 30 is formed so as to cover a whole surface of the display region 13 except for positions of slits 31 and cutouts 32. The common electrode 30 has the slits 31 corresponding to the pixel electrode 22 in order to generate, together with the pixel. electrode 22, a lateral electric field to be applied. to the liquid crystal layer. In FIG. 5, four slits 31 each bending around its middle are formed corresponding to one pixel electrode 22. It is possible to widen a view angle of the liquid crystal panel 2 by forming the bent slit 31 on the common electrode 30. Furthermore, the common electrode 30 has the cutout 32 formed in a same position as that of the TFT 21. It is possible to prevent that the common electrode 30 formed on the top of the TFT 21 affects an operation of the TFT 21, by providing the cutout 32 to the common electrode 30.

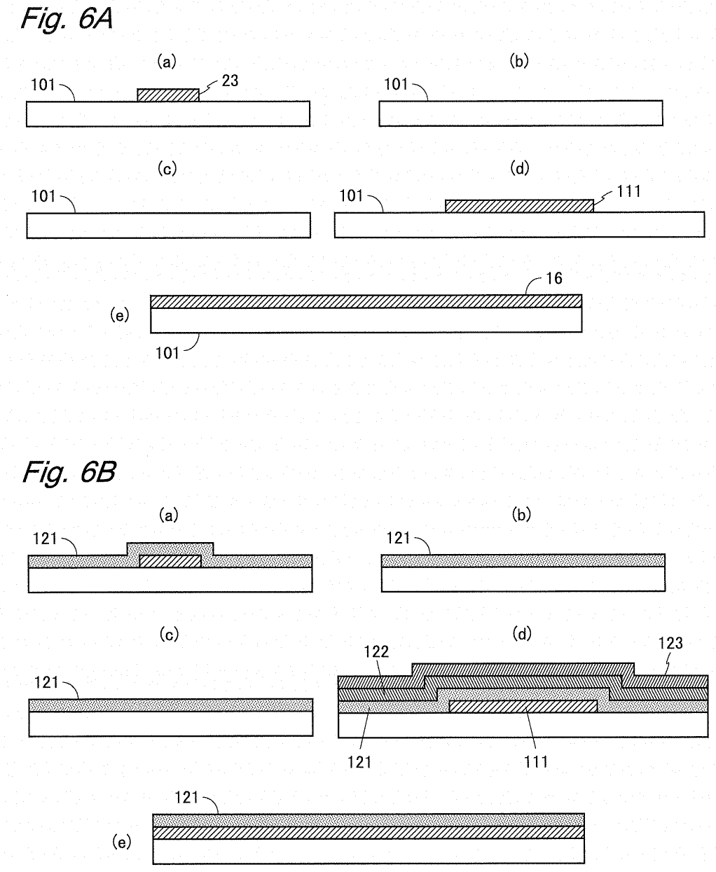

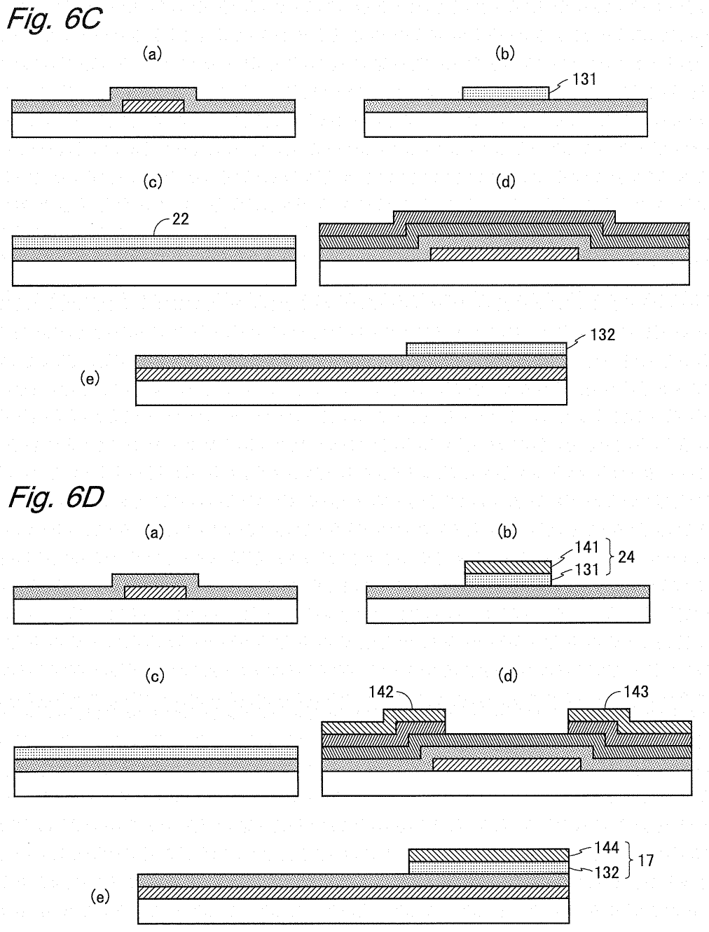

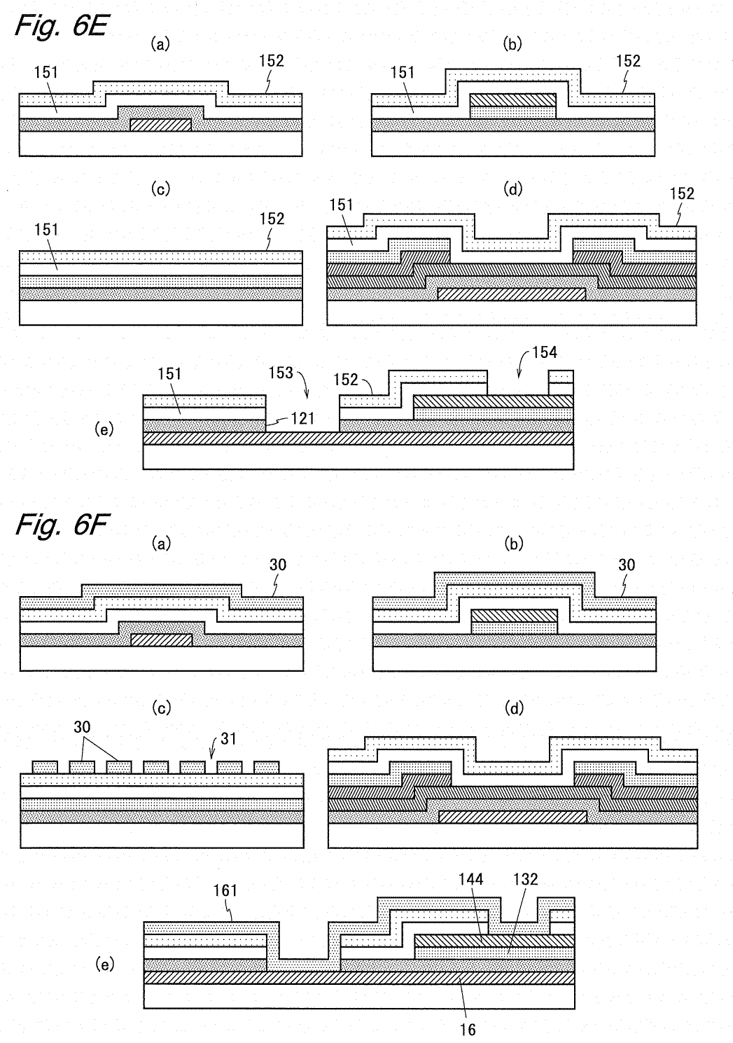

Hereinafter, a method for manufacturing the active matrix substrate 10 is described with reference to FIGS. 6A to 6F. Parts (a) to (e) in FIGS. 6A to 6F respectively describe processes of forming the gate line 23, the data line 24, a pixel opening portion (portion facing the opening of the counter substrate 40) the TFT 21, and the connecting circuit

(First Process) Formation of Gate Layer Pattern (FIG. 6A)

Ti (titanium), Al (aluminum) and Ti are sequentially formed on a glass substrate 101 by sputtering. Subsequently, the gate layer is patterned using photolithography and etching to form the gate line 23, a gate electrode 111 of the TFT 21, the first common main wiring 16, and the like. Patterning using photolithography and etching refers to the following processing.

First, a photoresist is applied to the substrate. Next, the substrate is covered with a photomask having an intended pattern and is exposed to light, thereby to make a photoresist having the same pattern as that of the photomask remain on the substrate. Next, the substrate is etched. using the remaining photoresist as a mask to form a pattern on the surface of the substrate. Finally, the photoresist is peeled off

(Second Process) Formation of Semiconductor Layer (FIG. 6B)

A SiNx (silicon nitride) film 121 to be the gate insulating film, an amorphous Si (amorphous silicon) film 122, and an n+amorphous Si film 123 doped with phosphorous are successively formed on the substrate shown in FIG. 6A by CVD (Chemical Vapor Deposition). Subsequently, the semiconductor layer is patterned using photolithography and etching to form the semiconductor layer including the amorphous Si film 122 and the n-amorphous Si film 123 on the gate electrode 111 of the TFT 21 in an island shape.

(Third Process) Formation of Pixel Electrode (FIG. 6C.)

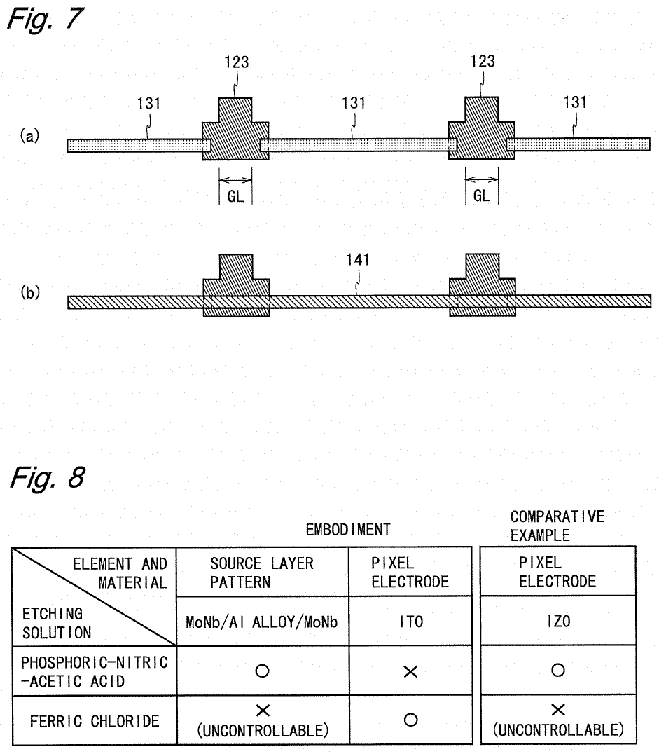

An ITO film to be the pixel electrode 22 is formed on the substrate shown in FIG. 6B by sputtering. Subsequently, the pixel electrode layer is patterned using photolithography and etching to form a lower layer conductor part 131 of the data line 24, the pixel electrode 22, a lower layer conductor part 132 of the second common main wiring 17, and the like. In the third process, the ITO film is not formed at a position of the TFT 21, and the lower layer conductor part 131 of the data line 24 is formed in a disconnected shape (in a perforation shape) at the position of the TFT 21 (see FIG. 7 described later). If the ITO film is formed using poly-ITO, wet etching is performed using ferric chloride. If the ITO film is formed using amorphous ITO, wet etching is performed using oxalic acid.

(Fourth Process) Formation of Source Layer Pattern (FIG. 6D)

MoNb, an Al alloy, and MoNb are sequentially formed on the substrate shown in FIG. 6C by sputtering. Subsequently, the source layer is patterned using photolithography and etching to form an upper layer conductor part 141 of the data line 24, a source electrode 142 and a drain electrode 143 of the TFT 21, an upper layer conductor part 144 of the second common main wiring 17, and the like. In the fourth process, the upper layer conductor part 141 of the data line 24 is formed in a continuous shape so as to overlap with the lower layer conductor part 131 of the data line 24 (see FIG. 7 described later). In the fourth process, a photomask for making the photoresist remain in a position of the pixel electrode layer pattern and a position of the source layer pattern is used. For this reason, after exposure to light, the photoresist remains in the position of the pixel electrode layer pattern and the position of the source layer pattern. Using the photoresist as a mask, a metal film having a three-layer structure is first etched by wet etching, and the n+amorphous Si film 123 existing at a position of a channel area of the TFT 21 is subsequently etched by dry etching. Finally, the photoresist is peeled off to obtain the substrate shown in FIG. 6D.

In the substrate shown in FIG. 6D, the source electrode 142 and the drain electrode 143 are formed with the channel area of the TFT 21 interposed therebetween. The lower layer conductor part 131 of the data line 24 exists in a layer under the upper layer conductor part 141 of the data line 24, and the lower layer conductor part 132 of the second common main wiring 17 exists in a layer under the upper layer conductor part 144 of the second common main wiring 17. The data line 24 is formed of the upper layer conductor part 141 and the lower layer conductor part 131, and the second common main wiring 17 is formed of the upper layer conductor part 144 and the lower layer conductor part 132. The upper layer conductor parts 141, 144 have a three-layer structure including MoNb, the Al alloy, and MoNb.

FIG. 7 is a schematic diagram of the data line 24. Note that in FIG. 7, unlike other drawings, the data line 24 is depicted so as to extend in a horizontal direction of the drawing. In FIG. 7, a symbol GL indicates an arrangement position of the gate line 23. In the third process, the lower layer conductor part 131 of the data line 24 is formed in the disconnected shape at the position of the TFT 21 (FIG. 7 (a)). More specifically, the lower layer conductor part 131 is formed in the disconnected shape at the arrangement position of the gate line GL which intersects with the data line 24. In FIG. 7 (a), a part of the lower layer conductor part 131 is formed so as to overlap with the n+amorphous Si film 123 which constitutes the TFT 21. Note that the lower layer conductor part 131 may be formed so as not to overlap with the n+amorphous Si film 123. In the fourth process, the upper layer conductor part. 141 of the data line 24 is formed in the continuous shape so as to overlap with the lower layer conductor part 131 of the data line 24 (FIG. 7 (b)) The data line 24 has a two-layer structure including the lower layer conductor part 131 and the upper layer conductor part 141.

(Fifth Process) Formation of Protective Insulating Film (FIG. 6E)

Two-layer SiNx films 151, 152 to be the protective insulating film are sequentially formed on the substrate shown in FIG. 6D by CVD. Film forming conditions for the lower SiNx film 151 and film forming conditions for the upper SiNx film 152 are different. For example, a high-density thin film formed under a high temperature condition is used as the lower SiNx film 151, and a low-density thick film formed under a low temperature condition is used as the upper SiNx film 152. Subsequently, the two-layer SiNx films 151, 152 formed in the fifth process and the SiNx film 121 formed in the second process are patterned using photolithography and etching. As shown in FIG. 6E (e), a contact hole 153 penetrating the two-layer SiNx films 151, 152 and the SiNx film 121, and a contact hole 154 penetrating the two-layer SiNx films 151, 152 are formed at a position for forming the connecting circuit.

(Sixth Process) Formation of Common Electrode (FIG. 6F)

An IZO film to be the common electrode 30 is formed on the substrate shown in FIG. 6F by sputtering. Subsequently, the common electrode layer is patterned using photolithography and. etching to form the common electrode 30 and a connecting electrode 161. As shown in FIG. 6F(c), the common electrode 30 having the slit 31 is formed in the pixel opening portion As shown in FIG. 6F(e), the connecting electrode 161 comes into direct contact with. the first common. main. wiring 16 at the position of the contact hole 153, and is electrically connected to the upper layer conductor part 144 of the second common main wiring 17 at the position of the contact hole 154. The connecting electrode 161 is formed monolithically with the common electrode 30. Therefore, the common electrode 30, the first common main wiring 16, and the second common main wiring 17 can be electrically connected using the connecting electrode 161. It is possible to manufacture the active matrix substrate having the sectional structure shown in FIG. 6F, by performing the first to sixth processes described above.

In the manufacturing method according to the present embodiment, photolithography is performed using different photomasks in. the first to sixth. processes. The number of photomasks used in the manufacturing method according to the present embodiment is six in total. When the gate line 23 is formed in the first process and when the upper layer conductor part 141 of the data line 24 is formed in the fourth process, Cu (copper), Mo (molybdenum), Al, Ti, or a laminated film of these metals may be used in place of the above materials. Furthermore, when the protective insulating film is formed in the fifth process, a single-layer SiNx film may be formed in place of the two-layer SiNx film. Furthermore, a SiOx (oxide silicon) film, a SiGN (nitride oxide silicon) film, or a laminated film of these may be used in place of the SiNx film. Furthermore, when the common electrode 30 is formed in the sixth process, ITC) may be used in place of IZO.

In the manufacturing method according to the present embodiment, thicknesses of a variety of films formed on the substrate are suitably decided in accordance with materials, functions and the like of the films. The thickness of the film is about 10 nm to 1 μm, for example. Hereinafter, one example of the film thickness is described. For example, in the first. process, the Ti film with a thickness of 25 to 35 nm, the Al film with a thickness of 180 to 220 nm, and the Ti film with a thickness of 90 to 110 nm are formed sequentially. In the second process, the SiNx film 121 with a thickness of 360 to 450 nm, the amorphous Si film 122 with a thickness of 100 to 200 nm, and the n+amorphous Si film 123 with a thickness of 30 to 80 nm are formed successively. In the third process, the ITO film with a thickness of 80 to 100 nm is formed. In the fourth process, the MoNb film with a thickness of 40 to 60 nm, the Al alloy film with a thickness of 120 to 180 nm, and the MoNb film with a thickness of 30 to 40 nm are formed sequentially. In the fifth process, the SiNx film 151 with a thickness of 220 to 280 nm and the SAN film 152 with a thickness of 450 to 550 nm are formed, and in the sixth process, the IZO film with a thickness of 110 to 140 nm is formed.

FIG. 8 is a diagram showing characteristics of etching solutions used in the third and fourth processes. In FIG. 8, a circle mark indicates that etching is possible and a cross mark indicates that etching is impossible. As shown in FIG. 8, although MoNb and the Al alloy used for forming the source layer pattern in the fourth process are etched using phosphoric-nitric-acetic acid, a line width and a taper size cannot be controlled if ferric chloride is used, because etching speed is too fast. One the other hand, although ITO used for forming the pixel electrode in the third process is etched using ferric chloride, it is not etched by phosphoric-nitric-acetic acid. Therefore, in the manufacturing method according to the present embodiment, ferric chloride is used as the etching solution in the third process, and phosphoric-nitric-acetic acid is used as the etching solution in the fourth process. Note that in place of ferric chloride, other chemical liquids (for example, oxalic acid) which can etch ITO may be used as the etching solution in the third process.

Hereinafter, the manufacturing method disclosed in International Publication No. WO2016/21319 is referred to as “manufacturing method according to a comparative example”, and the active matrix substrate manufactured by the manufacturing method according to the comparative example is referred to as “active matrix substrate according to the comparative example”.

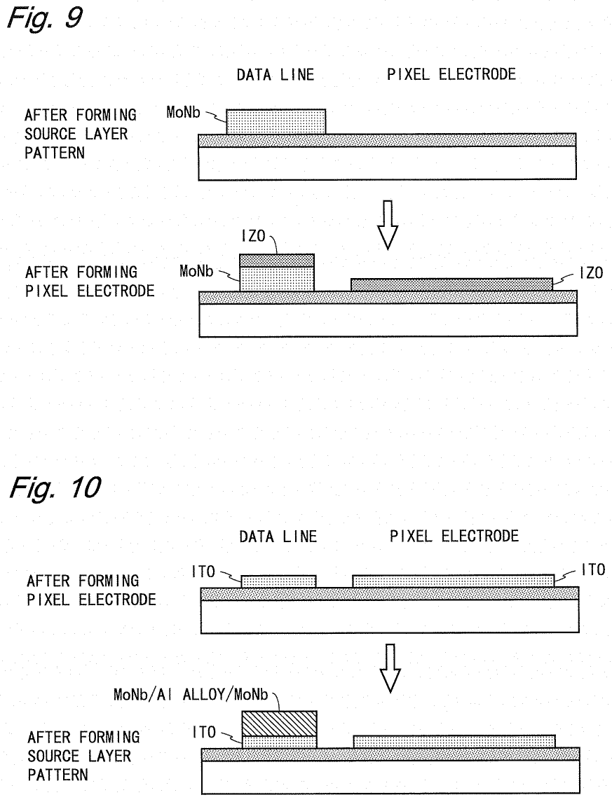

FIG. 9 is a diagram showing third and fourth processes of the manufacturing method according to the comparative example. In the manufacturing method according to the comparative example, after the source layer pattern is formed using MoNb in the third process, the pixel electrode is formed using IZO in the fourth process. Thus, the data line has a two-layer structure including a lower layer formed of MoNb and an upper layer formed of IZO.

FIG. 10 is a diagram showing the third and fourth processes of the manufacturing method according to the present embodiment. In the manufacturing method according to the present embodiment, after the pixel circuit 20 is formed using ITO in the third process, the source layer pattern is formed using MoNb/Al alloy/MoNb in the fourth process. Thus, the data line 24 has a two-layer structure including a lower layer (lower layer conductor part 131) formed of ITO and an upper layer (upper layer conductor part 141) formed of MoNb/Al alloy/MoNb.

In the following, effects of the active matrix substrate and the method for manufacturing the active matrix substrate according to the present embodiment are described, compared with the comparative example. In the manufacturing method according to the comparative example, if after the source layer pattern is formed using MoNb in the third process, the pixel electrode is formed using IZO in the fourth process, phosphoric-nitric-acetic acid is used as the etching solution.

for forming the source layer pattern and forming the pixel electrode (see FIG. 8). However, if after etching is performed: using phosphoric-nitric-acetic acid in the third. process, etching is performed using the same chemical liquid in the fourth process, overetching occurs. Thus, if there is a pattern failure on the data line, the data line is likely to be disconnected.

In contrast, in the manufacturing method according to the present embodiment, after the pixel electrode 22 and the lower layer conductor part 131 of and the data line 24 are formed using ITO in the third process, the source layer pattern (upper layer conductor part 141 of the data line 24, and the like) is formed using MoNb/Al alloy/MoNb in the fourth process. Ferric chloride is used as the etching solution for forming the pixel electrode 22 and the like, and phosphoric-nitric-acetic acid is used as the etching solution for forming the source layer pattern. Since ITO is not etched by phosphoric-nitric-acetic acid, even if after the lower layer conductor part 131 of the data line 24 is formed, the source layer pattern is etched using phosphoric-nitric-acetic acid, the lower layer conductor part 131 of the data line 24 is not overetched. Furthermore, the data line 24 has a redundant structure (two-layer structure) including the lower layer conductor part 131 and the upper layer conductor part 141. Thus, even when one of the lower layer conductor part 131 and the upper layer conductor part 141 is disconnected in the middle, the data line 24 is not disconnected if the other one is connected. Therefore, according to the active matrix substrate 10 according to the present embodiment, a disconnection failure of the data line can be prevented.

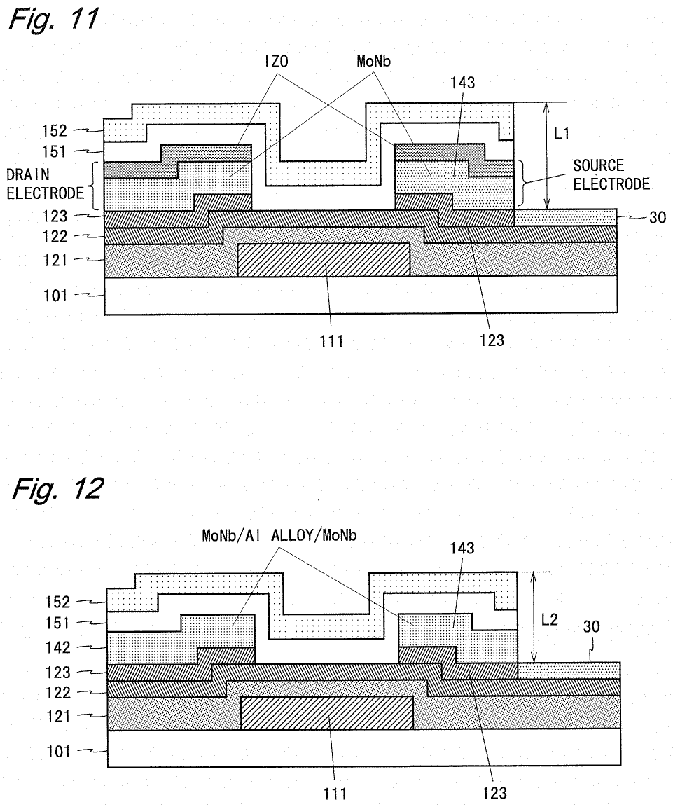

FIG. 11 is a sectional view of a TFT of the active matrix substrate according to the comparative example. FIG. 12 is a sectional view of the TFT 21 of the active matrix substrate 10 according to the present embodiment. Note that in order to compare the two drawings easily, same reference numerals as those provided to FIG. 12 are provided to FIG. 11. Generally, a film thickness of the active matrix substrate becomes maximum at a position where the TFT is formed.

In the active matrix substrate according to the comparative example (FIG. 11), the drain electrode and the source electrode of the TFT have the same two-layer structure as the data line (two-layer structure including MoNb and IZO). Thus, the film thickness becomes thick at the position where the TFT is formed, and a step difference occurs between the position where the TFT is formed and a surrounding portion. In an example shown in FIG. 11, the step difference L1 between the highest position of the TFT and the common electrode is 1.55 μm. If a rubbing process is performed on the active matrix substrate having the step difference, an alignment failure may occur and a display failure called a streak may occur.

In contrast, in the active matrix substrate 10 (FIG. 12) the ITO film is not formed at the positions of the source electrode 142 and the drain electrode 143 of the TFT 21. Thus, compared with the active matrix substrate according to the comparative example, the film thickness at the position where the TFT 21 is formed is thinner, and the step difference between the position. where the TFT 21 is formed and the surrounding portion is smaller. In an example shown in FIG. 12, the step difference L2 between the highest position of the TFT 21 and the common electrode 30 is 1.48 μm. In this manner, according to the active matrix substrate 10 according to the present embodiment, the step difference between the position where the TFT 21 is formed and the surrounding portion can be reduced, the alignment failure when the rubbing process is performed can be prevented, and the streak can be prevented.

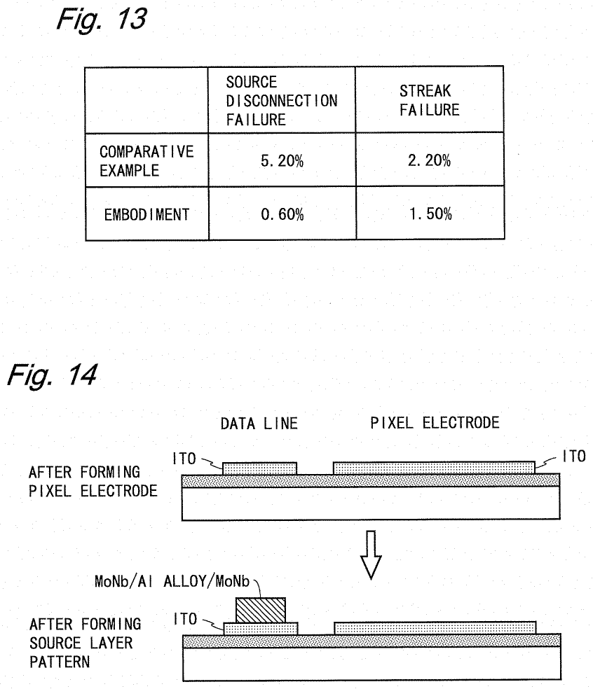

FIG. 13 is a diagram showing an example of failure rates of the active matrix substrates. FIG. 13 describes the failure rates of prototypes of the active matrix substrates. In the active matrix substrate according to the comparative example, an occurrence rate of a source line failure is 5.20%, and an occurrence rate of a streak failure is 2.20%. In contrast, in the active matrix substrate 10 according to the present embodiment, the occurrence rate of the source line failure is 0.60%, and the occurrence rate of the streak failure is 1.50 %. In this manner, according to the active matrix substrate 10 according to the present embodiment, the disconnection failure of the data line and the streak failure due to the alignment failure can be prevented.

Furthermore, whereas IZO and phosphoric-nitric-acetic acid are used when the pixel electrode is formed in the manufacturing method according to the comparative example, ITO and ferric chloride are used when the pixel electrode 22 is formed. in the manufacturing method according to the present. embodiment, ITO is less expensive than IZO, and ferric chloride is less expensive than phosphoric-nitric-acetic acid. Therefore, the active matrix substrate 10 according to the present embodiment can be manufactured with a cost lower than the active matrix substrate according to the comparative example.

Note that although the upper layer conductor part of the data line is formed so as to have a same line width as the lower layer conductor part in FIG. 10, the upper layer conductor part may be formed so as to have a line width narrower than that of the lower layer conductor part, as shown in FIG. 14. If the upper layer conductor part and the lower layer conductor part are formed so as to have a same line width and a pattern shift occurs, the upper layer conductor part and the lower layer conductor part are in a shifted state in a width direction. For this reason, a variation occurs in the distance between the data line 24 and the pixel electrode 22, and a variation occurs in parasitic capacitance between the data line 24 and the pixel electrode 22. If the upper layer conductor part is formed so as to have a line width narrower than that of the lower layer conductor part, the distance between the data line 24 and the pixel electrode 22 becomes constant, because a cross section of the data line 24 has a convex shape. Therefore, the variation in the parasitic capacitance between the data line 24 and the pixel electrode 22 can be prevented. Furthermore, since the cross section of the data line 24 has a convex shape and a taper shape, a crack is unlikely to occur on the protective insulating film formed over the data line 24.

As described above, the active matrix substrate 10 according to the present embodiment includes the gate lines 23, the data lines 24, the pixel circuits 20 arranged corresponding to the intersections of the gate lines 23 and the data lines 24 and each including a switching element (TFT 21) and the pixel electrode 22, a protective insulating (SiNx films 151, 152) formed in a layer over the gate line 23, the data line 24, the switching element, and the pixel electrode 22, and the common electrode 30 formed in a layer over the protective insulating film. The data line 24 includes the lower layer conductor part 131 formed using ITO together with the pixel electrode 22, and the upper layer conductor part 141 formed using metal materials (MoNb/Al alloy/MoNb) other than ITO. The lower layer conductor part 131 is formed in a disconnected shape at the position of the switching element, and the upper layer conductor part 141 is formed in a continuous shape so as to overlap with the lower layer conductor part 131. The lower layer conductor part 131. is formed in a disconnected shape at the arrangement position of the gate line 23.

According to the active matrix substrate 10 according to the present embodiment, it is possible to prevent overetching of the lower layer conductor part 131 of the data line 24 by suitably selecting the etching solution used for forming the pixel electrode. 22 and the like, and the etching solution used for forming the source layer pattern. Furthermore, the data line 24 has a redundant structure including the lower layer conductor part 131 and the upper layer conductor part 141 Therefore, the disconnection failure of the data line 24 can be prevented. Furthermore, since the lower layer conductor part 131 is not formed at the position of the switching element, the step difference between the position where the switching element is formed and the surrounding portion can be reduced, the alignment failure when the rubbing process is performed can be prevented, and the streak can be prevented.

Furthermore, the upper layer conductor part 141 is formed using MoNb and the Al alloy. The upper layer conductor part 141 is formed so as to have a three-layer structure including MoNb, the Al alloy, and MoNb. Therefore, the above effects can be attained using ferric chloride or oxalic acid as the etching solution for forming the pixel electrode 22 and the like, and using phosphoric-nitric-acetic acid as the etching solution for forming the source layer pattern. Furthermore, the variation in the parasitic capacitance between the data line 24 and the pixel electrode 22 can be prevented by forming the upper layer conductor part 141 so as to have a line width narrower than that of the lower layer conductor part 131. Furthermore, the common electrode 30 has the slits 31 corresponding to the pixel electrode 22. Therefore, a lateral electric field can be applied to the liquid crystal layer using the common electrode 30 and the pixel electrode 22.

Furthermore, the method for manufacturing the active matrix substrate 10 according to the present embodiment includes forming the gate lines 23 and the gate electrodes 111 of the switching elements in a first ring layer (first process), forming the gate insulating film (SiNx film 121) and a semiconductor film (amorphous Si film 122 and n+amorphous Si film 123) (second process), forming the pixel electrode layer by forming the pixel electrodes 22 and the lower layer conductor parts 131 of the data lines 24 using ITO in the pixel electrode layer (third process), forming the source layer by forming the upper layer conductor parts 141 of the data lines 24 and the conduction electrodes (source electrode 142 and the drain electrode 143) of the switching elements using a metal material other than. ITO in a second wiring layer and patterning the semiconductor film (fourth process), forming the protective insulating film in a layer over the pixel electrode 22 (fifth process), and forming the common electrode 30 in a layer over the protective insulating film (sixth process). In forming the pixel electrode layer, the lower layer conductor part 131 is formed in a disconnected shape at the position of the switching element, and in forming the source layer, the upper layer conductor part 141 is formed in a continuous shape so as to overlap with the lower layer conductor part 131. In forming the pixel electrode layer, the lower layer conductor part 131 is formed in a disconnected shape at the arrangement position of the gate line 23. Furthermore, in forming the source layer, the upper layer conductor part 1141 and the conduction electrode are formed using MoNb and the Al alloy. Furthermore, in forming the source layer, the upper layer conductor part 141 and the conduction electrode are formed so as to have a three-layer structure including MoNb, the Al alloy, and MoNb. In forming the source layer, the upper layer conductor part 141 may be formed so as to have a line width narrower than that of the lower layer conductor part 131. Furthermore, in forming the common electrode 30, the common electrode 30 is formed so as to have the slits 31 corresponding to the pixel electrode 22. With this, the active matrix substrate 10 which attains the above effects can be manufactured.

Furthermore, in forming the pixel electrode layer, etching is performed using ferric chloride or oxalic acid, and in forming the source layer, etching is performed using an etching solution which does not etch indium tin oxide. Therefore, in forming the source layer, a suitable etching solution which does not etch indium tin oxide can be selected. It is desirable that etching be performed using phosphoric-nitric-acetic acid in forming the source layer. With this, the active matrix substrate 10 which attains the above effects can be manufactured at low cost.

Note that although an active matrix substrate of a liquid crystal panel of a lateral electric field system has been described so far, an active matrix substrate of a liquid crystal panel of a vertical electric field system and an active matrix substrate of an organic EL (Electro Luminescence) display device can be configured by a similar method. Furthermore, an active matrix substrate including a TFT using an oxide semiconductor, such as IGZO (Indium Gallium Zinc Oxide), can be configured by a similar method.

Although the present invention is described in detail in the above, the above description is exemplary in all of the aspects and is riot restrictive. It is understood that various other changes and modification can be derived without going out. of the present invention.

What is claimed is:

1. An active matrix substrate comprising:
gate lines;
data lines;
pixel circuits arranged corresponding to intersections of the gate lines and the data lines and each including a switching element and a pixel electrode;
a protective insulating film formed in a layer over the gate line, the data line, the switching element, and the pixel electrode; and
a common electrode formed in a layer over the protective insulating film, wherein
the data line includes a lower layer conductor part formed using indium tin oxide together with the pixel electrode, and an upper layer conductor part formed using a metal material other than indium tin oxide,
the lower layer conductor part is formed in a disconnected shape at a position of the switching element, and
the upper layer conductor part is formed in a continuous shape so as to overlap with the lower layer conductor part.

2. The active matrix substrate according to claim 1, wherein the lower layer conductor part is formed in a disconnected shape at an arrangement position of the gate line.

3. The active matrix substrate according to claim 1, wherein the upper layer conductor part is formed using molybdenum niobium and an aluminum alloy.

4. The active matrix substrate according to claim 3, wherein the upper layer conductor part has a three-layer structure including molybdenum niobium, the aluminum alloy, and molybdenum niobium.

5. The active matrix substrate according to claim 1, wherein the upper layer conductor part is formed so as to have a line width narrower than that of the lower layer conductor part.

6. The active matrix substrate according to claim 1, wherein the common. electrode has slits corresponding to the pixel electrode.

7. A method for manufacturing an active matrix substrate, comprising:
forming gate lines and gate electrodes of switching elements in a first wiring layer;
forming a gate insulating film and a semiconductor film;
forming a pixel electrode layer by forming pixel electrodes and lower layer conductor parts of data lines in the pixel electrode layer using indium tin oxide;
forming a source layer by forming upper layer conductor parts of the data lines and conduction electrodes of the switching elements in a second wiring layer using a metal material other than indium tin oxide and patterning the semiconductor film;
forming a protective insulating film in a layer over the pixel electrode; and.
forming a common electrode in a layer over the protective insulating film, wherein
in forming the pixel electrode laver, the lower layer conductor part is formed. in a disconnected shape at a position of the switching element, and.
in forming the source layer, the upper layer conductor part is formed in a continuous shape so as to overlap with the lower layer conductor part.

8. The method for manufacturing the active matrix substrate according to claim 7, wherein in forming the pixel electrode layer, the lower layer conductor part is formed in a disconnected shape at an arrangement position of the gate line.

9. The method for manufacturing the active matrix substrate according to claim 7, wherein in forming the source layer, the upper layer conductor part and the conduction electrode are formed using molybdenum niobium and an aluminum alloy.

10. The method for manufacturing the active matrix substrate according to claim 9, wherein in forming the source layer, the upper layer conductor part and the conduction electrode are formed so as to have a three-layer structure including molybdenum niobium, the aluminum alloy, and molybdenum niobium,

11. The method for manufacturing the active matrix substrate according to claim 7, wherein
in forming the pixel electrode layer, etching is performed us rig ferric chloride or oxalic acid, and
in forming the source layer, etching is performed using an etching solution which does not etch indium tin oxide.

12. The method for manufacturing the active matrix substrate according to claim 11, wherein in forming the source layer, etching is performed using phosphoric-nitric-acetic acid.

13. The method for manufacturing the active matrix substrate according to claim 7, wherein in forming the source layer, the upper layer conductor part. is formed so as to have a line width narrower than that of the lower layer conductor part.

14. The method for manufacturing the active matrix substrate according to claim 7, wherein in forming the common electrode, the common electrode is formed so as to have slits corresponding to the pixel electrode.
